(19) United States
(12) Patent Application Publication
(10) Pub. No.: US 2015/0069496 A1
(43) Pub. Date: Mar. 12, 2015

(54) SEMICONDUCTOR STORAGE DEVICE

(71) Applicant: KABUSHIKI KAISHA TOSHIBA, Tokyo (JP)

(72) Inventor: Hidehiro SHIGA, Kanagawa (JP)

(73) Assignee: KABUSHIKI KAISHA TOSHIBA, Tokyo (JP)

(21) Appl. No.: 14/189,892

(22) Filed: Feb. 25, 2014

(30) Foreign Application Priority Data
Sep. 10, 2013 (JP) 2013-187328

(51) Int. Cl. H01L 27/115

(52) U.S. Cl. CPC H01L 27/11578
USPC 257/324

(57) ABSTRACT

A semiconductor storage device includes a semiconductor substrate, first and second word lines that are stacked above the substrate, extend in a row direction, are electrically connected together, and are separated from each other by a first region, and third and fourth word lines that are stacked above the substrate, extend in the row direction, are electrically connected together, and are separated from each other by a second region. The position of the first region is offset with respect to a position of the second region in the row direction.

### CROSS-REFERENCE TO RELATED APPLICATION

This application is based upon and claims the benefit of priority from Japanese Patent Application No. 2013-187328, filed Sep. 10, 2013, the entire contents of which are incorporated herein by reference.

### FIELD

Embodiments described herein relate generally to a stacked-type semiconductor storage device.

### BACKGROUND

Recently, there have been many different proposals for a semiconductor storage device where memory cells are arranged three-dimensionally (stacked-type semiconductor storage device) for increasing the degree of integration of memory cells in the semiconductor storage device.

### DESCRIPTION OF THE DRAWINGS

FIG. 1 is a block diagram showing the configuration of a semiconductor storage device according to a first embodiment.

FIG. 2 is a circuit diagram of a portion of a memory cell array of the semiconductor storage device according to the first embodiment.

FIG. 3 is a perspective view of the portion of the memory cell array of the semiconductor storage device according to the first embodiment.

FIG. 4 is a cross-sectional view of the portion of the memory cell array of the semiconductor storage device according to the first embodiment.

FIG. 5 is a plan view showing the configuration of a portion of a memory cell array of a semiconductor storage device according to a reference example.

FIG. 6 is a plan view of the portion of the memory cell array of the semiconductor storage device according to the first embodiment.

FIG. 7 is a plan view showing an example of a layout of wires according to the first embodiment.

FIG. 8 is a cross-sectional view of the portion of the memory cell array of the semiconductor storage device according to the first embodiment.

FIG. 9 is a cross-sectional view for illustrating a method of manufacturing the semiconductor storage device according to the first embodiment.

FIG. 10 is a cross-sectional view for illustrating the method of manufacturing the semiconductor storage device according to the first embodiment.

FIG. 11 is a cross-sectional view for illustrating the method of manufacturing the semiconductor storage device according to the first embodiment.

FIG. 12 is a cross-sectional view for illustrating the method of manufacturing the semiconductor storage device according to the first embodiment.

FIG. 13 is a cross-sectional view for illustrating the method of manufacturing the semiconductor storage device according to the first embodiment.

FIG. 14 is a cross-sectional view for illustrating the method of manufacturing the semiconductor storage device according to the first embodiment.

FIG. 15 is a cross-sectional view for illustrating the method of manufacturing the semiconductor storage device according to the first embodiment.

FIG. 16 is a cross-sectional view for illustrating the method of manufacturing the semiconductor storage device according to the first embodiment.

FIG. 17 is a cross-sectional view for illustrating the method of manufacturing the semiconductor storage device according to the first embodiment.

FIG. 18 is a cross-sectional view for illustrating the method of manufacturing the semiconductor storage device according to the first embodiment.

FIG. 19 is a cross-sectional view for illustrating the method of manufacturing the semiconductor storage device according to the first embodiment.

FIG. 20 is a cross-sectional view of a portion of a memory cell array of a semiconductor storage device according to a second embodiment.

FIG. 21 is a cross-sectional view for illustrating a method of manufacturing the semiconductor storage device according to the second embodiment.

FIG. 22 is a cross-sectional view for illustrating the method of manufacturing the semiconductor storage device according to the second embodiment.

FIG. 23 is a cross-sectional view for illustrating the method of manufacturing the semiconductor storage device according to the second embodiment.

FIG. 24 is a cross-sectional view for illustrating the method of manufacturing the semiconductor storage device according to the second embodiment.

FIG. 25 is a cross-sectional view for illustrating the method of manufacturing the semiconductor storage device according to the second embodiment.

FIG. 26 is a cross-sectional view for illustrating the method of manufacturing the semiconductor storage device according to the second embodiment.

FIG. 27 is a cross-sectional view for illustrating the method of manufacturing the semiconductor storage device according to the second embodiment.

FIG. 28 is a cross-sectional view for illustrating the method of manufacturing the semiconductor storage device according to the second embodiment.

FIG. 29 is a plan view of a portion of a memory cell array of a semiconductor storage device according to a third embodiment.

FIG. 30 is a perspective view of the portion of the memory cell array of the semiconductor storage device according to the third embodiment.

FIG. 31 is a perspective view for illustrating a method of manufacturing the semiconductor storage device according to the third embodiment.

FIG. 32 is a perspective view for illustrating the method of manufacturing the semiconductor storage device according to the third embodiment.

FIG. 33 is a perspective view for illustrating the method of manufacturing the semiconductor storage device according to the third embodiment.

FIG. 34 is a plan view of a portion of a memory cell array of a semiconductor storage device according to another embodiment.

FIG. 35 is a plan view of a portion of a memory cell array of a semiconductor storage device according to another embodiment.

### DETAILED DESCRIPTION

According to an embodiment, there is provided a semiconductor storage device where a size of block can be desirably set.

In general, according to one embodiment, a semiconductor storage device includes a semiconductor substrate, a plurality of first word lines that are stacked above the substrate and extend in a row direction, a plurality of second word lines that are stacked above the substrate, extend in the row direction, are electrically connected to the first word lines, and are separated from the first word lines by a first region, a plurality of third word lines that are stacked above the substrate and extend in the row direction, and a plurality of fourth word lines that are stacked above the substrate, extend in the row direction, are electrically connected to the third word lines, and are separated from the third word lines by a second region. The position of the first region is offset with respect to a position of the second region in the row direction.

Hereinafter, semiconductor storage devices according to embodiments are explained in conjunction with the drawings.

### Configuration of Semiconductor Storage Device According to First Embodiment

### [Overall Configuration]

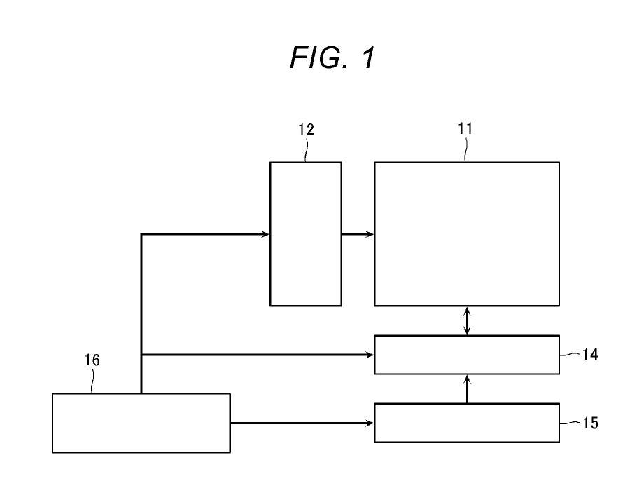

Firstly, a semiconductor storage device according to the first embodiment is explained in conjunction with FIG. 1 to FIG. 19. FIG. 1 is a block diagram of the semiconductor storage device according to the first embodiment.

As shown in FIG. 1, the semiconductor storage device of this embodiment includes: a memory cell array 11; a row decoder 12 which controls reading and writing of data from and into the memory cell array 11; a sense amplifier 14; a column decoder 15; and a control signal generating unit (high voltage generating unit) 16.

The row decoder 12 decodes a row address signal, a block address signal or the like inputted to the row decoder 12, and performs a control of the memory cell array 11 in the row direction. The sense amplifier 14 reads out data from the memory cell array 11 in a read operation and writes data from a host computer or an external controller not shown in the drawing into the memory cell array 11 in a write operation. The column decoder 15 decodes a column address signal and controls the sense amplifier 14. The control signal generating unit 16 generates a high voltage need for writing or erasing data by boosting a reference voltage. The control signal generating unit 16 also generates a control signal so as to control the row decoder 12, the sense amplifier 14 and the column decoder 15.

### [Memory Cell Array 11]

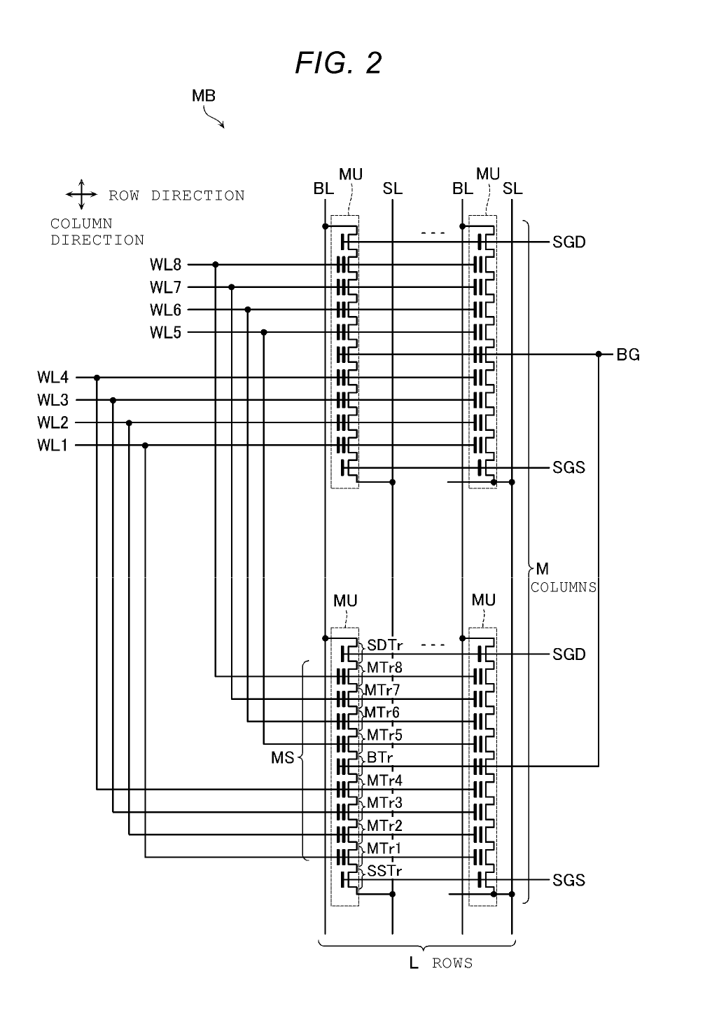

The memory cell array 11 includes a plurality of memory blocks MB. FIG. 2 is a circuit diagram showing the configuration of a portion of the memory block MB. The memory block MB includes: a plurality of bit lines BL; a plurality of source lines SL; and a plurality of memory units MU which are connected to these bit lines BL and source lines SL.

The memory unit MU is a NAND-type flash memory, wherein a source-side selection transistor SSTr and a drain-side selection transistor SDTr are connected to both ends of a memory string MS that includes memory transistors MTr1 to MTr8 and a back gate transistor BTr which are connected in series. Each of the memory transistors MTr1 to MTr8 changes a threshold voltage thereof by storing electric charges in a charge storage layer, and holds data corresponding to the threshold voltage.

Word lines WL1 to WL8 are connected to gates of the memory transistors MTr1 to MTr8 respectively. A back gate line BG is commonly connected to gates of the back gate transistors BTr. A source-side selection gate line SGS is connected to a gate of the source-side selection transistor SSTr, and a drain-side selection gate line SGD is connected to a gate of the drain-side selection transistor SDTr.

In this embodiment, a plurality of memory units MU to which the word lines WL1 to WL8 are commonly connected and which are connected in the column direction as well as in the row direction constitute the memory block MB. Erasing of data in the memory block MB is performed using the whole memory block MB or a portion of the memory block MB as an erasure unit.

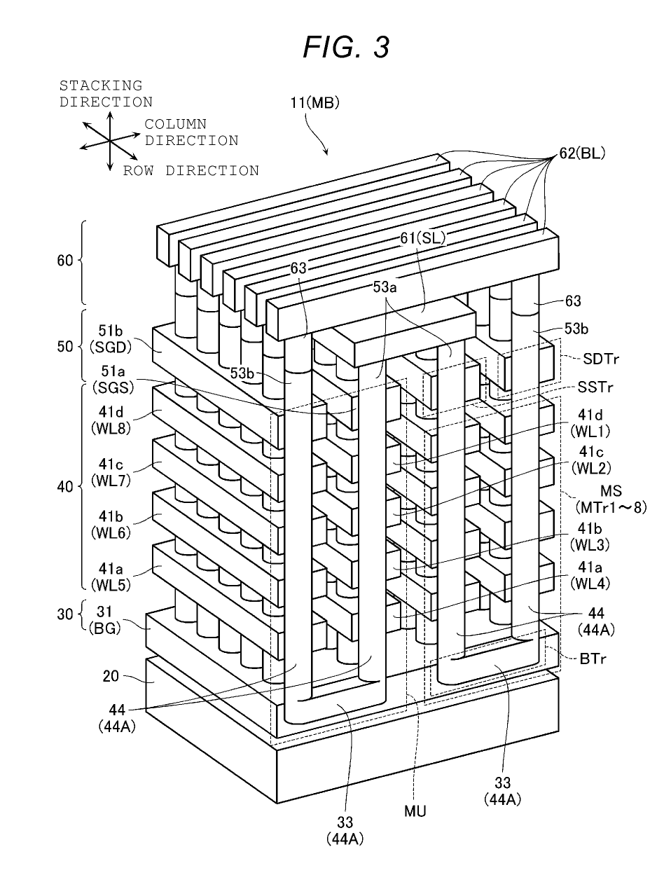

FIG. 3 is a perspective view showing the configuration of the portion of the memory block MB. The memory block MB includes: a back gate layer 30; a memory layer 40; a selection transistor layer 50; and a wiring layer 60 which are sequentially stacked on a semiconductor substrate 20. The back gate layer 30 functions as the back gate transistor BTr. The memory layer 40 functions as the memory transistors MTr1 to MTr8. The selection transistor layer 50 functions as the drain-side selection transistor SDTr and the source-side selection transistor SSTr. The wiring layer 60 functions as the source lines SL and the bit lines BL.

As shown in FIG. 3, the back gate layer 30 includes a back gate conductive layer 31. The back gate conductive layer 31 functions as the back gate line BG and a gate of the back gate transistor BTr. The back gate layer 30 includes a semiconductor layer 33 and a memory gate insulation layer not shown in the drawing which is formed between the back gate layer 30 and the semiconductor layer 33. The semiconductor layer 33 functions as a body (channel) of the back gate transistor BTr.

The semiconductor layers 33 are arranged in a matrix array in the row direction as well as in the column direction in one memory block MB.

As shown in FIG. 3, the memory layer 40 is formed on the back gate layer 30. The memory layer 40 includes four word line conductive layers 41a to 41d stacked in layers. The word line conductive layers 41a to 41d function as the word lines WL1 to WL8 and gates of the memory transistors MTr1 to MTr8 respectively. The word line conductive layers 41a to 41d are arranged parallel to each other at a desired pitch in the column direction and extend in the row direction which is the longitudinal direction.

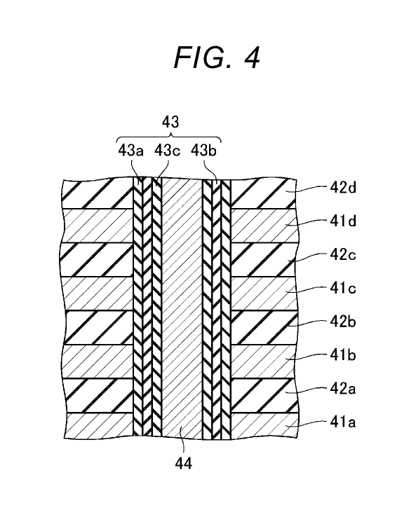

FIG. 4 is a longitudinal cross-sectional view showing a portion of the memory layer 40. As shown in FIG. 4, the word line conductive layers 41a to 41d are stacked with interlayer insulation layers 42a to 42d sandwiched therebetween vertically. The word line conductive layers 41a to 41d are formed using poly-silicon (poly-Si), for example. The memory layer 40 also includes memory gate insulation layers 43 and columnar semiconductor layers 44. The columnar semiconductor layers 44 function as bodies (channels) of the memory transistors MTr1 to MTr8.

The memory gate insulation layer 43 is in contact with side surfaces of the word line conductive layers 41a to 41d. The memory gate insulation layer 43 is continuously and integrally formed with the memory gate insulation layer in the above-mentioned back gate layer 30. The memory gate insulation layer 43 includes a block insulation layer 43a, a charge storage layer 43b and a tunnel insulation layer 43c in order from a side surface side of the word line conductive layers 41a to 41d to a columnar semiconductor layer 44 side.

In the back gate layer 30 and the memory layer 40 described above, a pair of columnar semiconductor layers 44 and the semiconductor layer 33 which connects lower ends of the columnar semiconductor layers 44 to each other constitute a memory semiconductor layer 44A which functions as a body (channel) of the memory string MS. The memory semiconductor layer 44A is formed in a U shape as viewed in the row direction. The memory unit MU includes the plurality of memory transistors MTr1 to MTr8 which share one memory semiconductor layer 44A in common, and the source-side selection transistor SSTr and the drain-side selection transistor SDTr, which are connected to the plurality of memory transistors MTr1 to MTr8.

As shown in FIG. 3, the selection transistor layer 50 includes a source-side conductive layer 51a and a drain-side conductive layer 51b. The source-side conductive layer 51a functions as the source-side selection gate line SGS and a gate of the source-side selection transistor SSTr. The drain-side conductive layer 51b functions as the drain-side selection gate line SGD and a gate of the drain-side selection transistor SDTr.

The wiring layer 60 includes source line layers 61, bit line layers 62 and plug layers 63. The source line layers 61 function as source lines SL. The bit line layers 62 function as the bit lines BL.

The source line layer 61 is in contact with upper surfaces of the source-side columnar semiconductor layers 53a and extends in the row direction. The bit line layers 62 are in contact with upper surfaces of the drain-side columnar semiconductor layers 53b with plug layers 63 sandwiched therebetween, and extend in the column direction.

The configuration of the memory cell array is described in U.S. patent application Ser. No. 12/407,403 filed on Mar. 19, 2009 entitled “three-dimensional laminated non-volatile semiconductor memory”, for example. The configuration of the memory cell array is also described in U.S. patent application Ser. No. 12/406,524 filed on Mar. 18, 2009 entitled “three-dimensional laminated non-volatile semiconductor memory”, U.S. patent application Ser. No. 12/679,991 filed on Mar. 25, 2010 entitled “non-volatile semiconductor storage device and method of manufacturing the same”, and U.S. patent application Ser. No. 12/532,030 filed on Mar. 23, 2009 entitled “semiconductor memory and manufacturing method thereof”. The entire contents of these patent applications are incorporated by reference herein.

### [Contact Structure]

Next, the contact structure among the memory cell array 11, the word lines WL and the selection gate lines SGS, SGD according to this embodiment is explained.

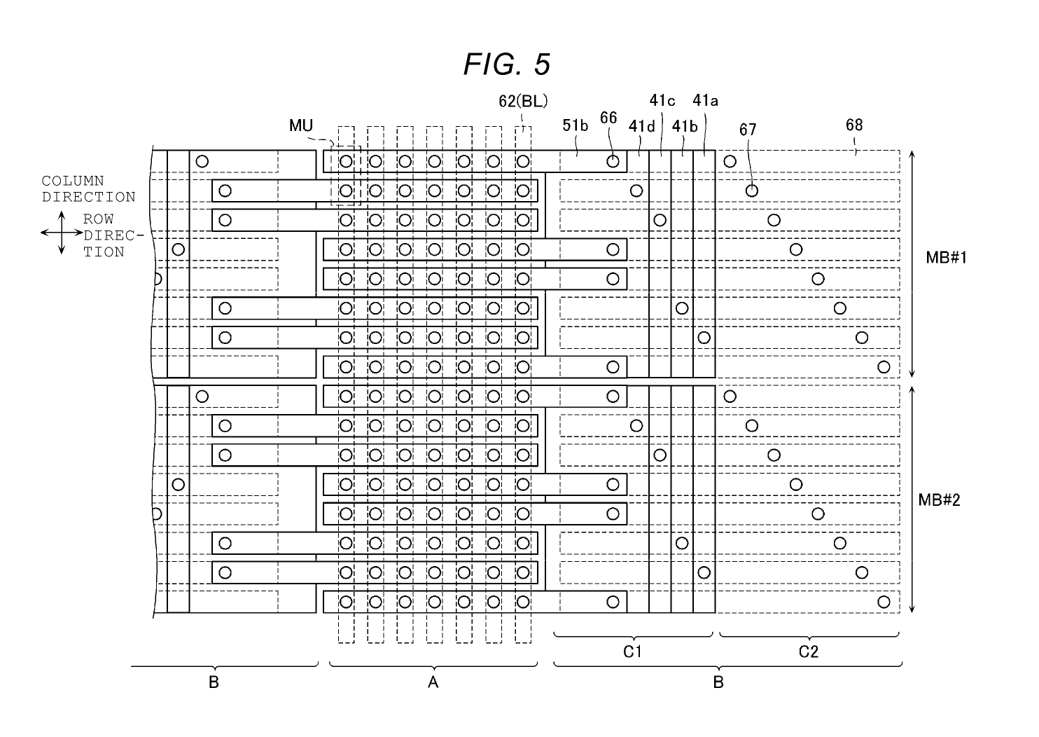

Firstly, to facilitate the understanding of the memory cell array 11 according to this embodiment, the contact structure of a reference example is explained. FIG. 5 is a plan view of the memory cell array 11 according to the reference example. In FIG. 5, to simplify the explanation, the source lines 61 (FIG. 3) are omitted.

In FIG. 5, a memory transistor region A is a region where the memory units MU shown in FIG. 3 are arranged in a matrix array. On both sides of the memory transistor region A in the row direction, a contact region B formed of the word line conductive layers 41a to 41d and the drain-side conductive layers 51b is formed. The contact region B includes a first contact region C1 and a second contact region C2. In the drawing, to focus on the contact region B on a right side, in the first contact region C1, with respect to end portions of the word line conductive layers 41a to 41d and the drain-side conductive layers 51b in the row direction, end portions of conductive layers at lower positions are shown to project more toward a second contact region C2 side. The end portions of the word line conductive layers 41a to 41d and the drain-side conductive layers 51b in the row direction are connected with the wires 68 arranged above these layers via first contacts 66 in the first contact region C1. The wires 68 extend in the row direction orthogonal to the bit lines BL and are arranged parallel to each other in the column direction at a desired pitch. Neither the word line conductive layers 41a to 41d nor the drain-side conductive layers 51b are present in the second contact region C2. The wires 68 are connected with a circuit such as a row decoder formed on the semiconductor substrate 20 (FIG. 3) via second contacts 67 in the second contact region C2.

In such a contact structure, assuming the number of layers of the word line conductive layers 41a to 41d as Nw and the number of memory strings MS formed in the column direction in one memory block MB as Ns, in one memory block MB, the number of wires 68 for ensuring the connection of the word line conductive layers 41a to 41d becomes Nw (Nw=4 in this example), and the number of wires 68 for ensuring the connection of the drain-side conductive layers 51b becomes Ns (Ns=4 in this example). Accordingly, the number M of wires 68 necessary for ensuring the contact of all word line conductive layers 41a to 41d and drain-side conductive layers 51b becomes M=Nw+Ns (M=8 in this example). Assuming that a width of the wire 68 in the column direction is substantially equal to a width of the word line conductive layers 41a to 41d in the memory transistor region A, a plurality of memory units MU which are connected to eight wires 68 constitute one memory block MB. Accordingly, a width of the memory block MB becomes substantially equal to a width of M(=8) pieces of wires 68. The number Nw of wires 68 for ensuring the connection of the word line conductive layers 41a to 41d is equal to the number of layers of the word line conductive layers 41a to 41d and hence, when the number of layers of the word line conductive layers 41a to 41d is increased, a size of the memory block MB is also increased. When the size of the memory block MB becomes excessively large, there arises a drawback that compatibility with a flat-type NAND flash memory is impaired in addition to lowering of controllability in data rewriting. Further, in controlling failures using a memory block MB as a unit, when a size of the memory block MB is large, there arises a drawback in that the likelihood of a data volume which becomes a bad block is also increased.

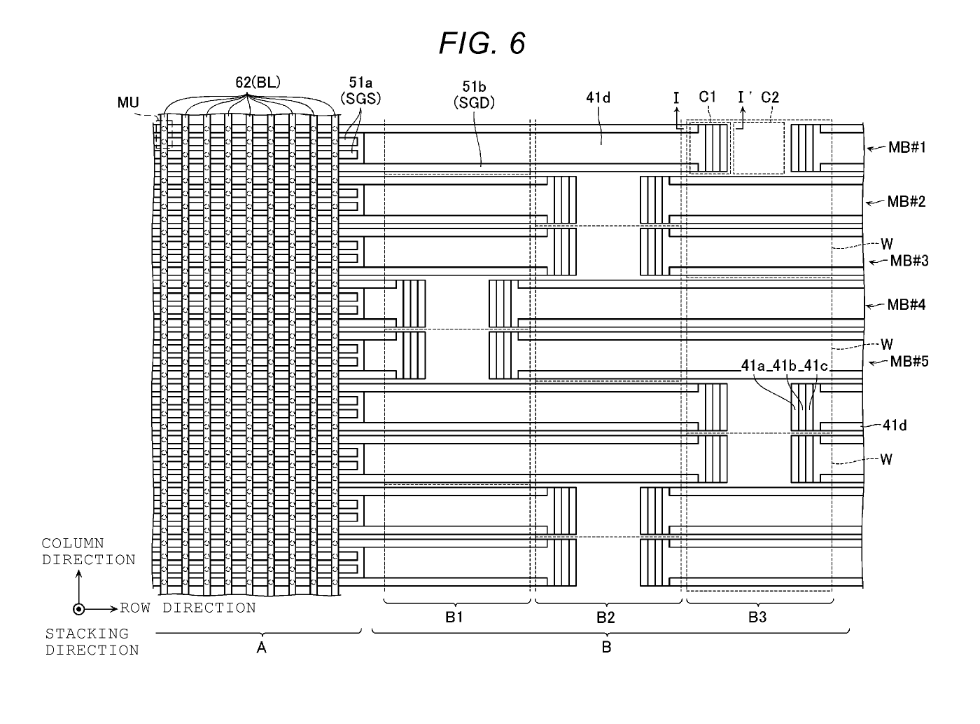

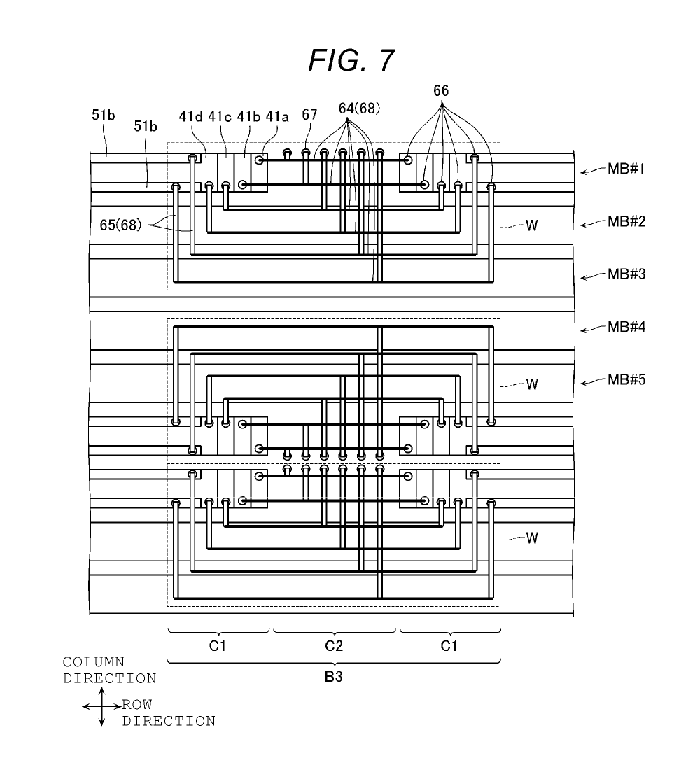

Next, the contact structure of the memory cell array 11 according to this embodiment is explained. FIG. 6 is a plan view of the memory cell array 11 according to this embodiment. In FIG. 6, to simplify the explanation, the source lines 61 (FIG. 3), the contacts and the wires are omitted. FIG. 7 is a plan view showing an enlarged part of FIG. 6, and illustrates the contacts and the wires.

In FIG. 6, a memory transistor region A is a region where the memory units MU shown in FIG. 3 are arranged in a matrix array. On both sides of the memory transistor region A in the row direction, a contact region B formed of the word line conductive layers 41a to 41d and the source-side conductive layers 51a and the drain-side conductive layers 51b is formed. In this embodiment, the contact region B includes three contact regions B1, B2, B3 which differ from each other in position in the row direction. For every memory block MB, one of the contact regions B1, B2, B3 includes a first contact region C1 and a second contact region C2. In this embodiment, the first contact region C1 and the second contact region C2 in the first memory block MB#1 are provided in the contact region B3, the first contact region C1 and the second contact region C2 of a second memory block MB#2 and a third memory block MB#3 are provided in the contact region B2, and the first contact region C1 and the second contact region C2 of a fourth memory block MB#4 and a fifth memory block MB#5 are provided in the contact region B1.

FIG. 7 is a plan view showing an example of a layout of the wires 64, 65. To focus on the wire layout of the first memory block MB#1, as shown in the drawing, the wires 64, 65 are laid out in a region above the first memory block MB#1, and in regions above the second memory block MB#2 and the third memory block MB#3 arranged adjacent to the first memory block MB#1 in the column direction.

In this manner, in the memory cell array 11 according to this embodiment, the first contact region C1 and the second contact region C2 are displaced in the row direction between the neighboring memory blocks MB, and spaces above the other memory blocks MB are used as arrangement spaces for the wires 64, 65. Accordingly, a width of the memory block MB in the column direction can be set smaller than a width of the memory block MB in the reference example shown in FIG. 5. In this example, a width corresponding to a sum of widths of two memory units MU arranged adjacent to each other in the column direction agrees with the width of the memory block MB. To compare this example with the reference example shown in FIG. 5, the width of the memory block MB becomes substantially equal to a sum of widths of M(=4) pieces of the wires 68 and hence, the width of the memory block MB is halved.

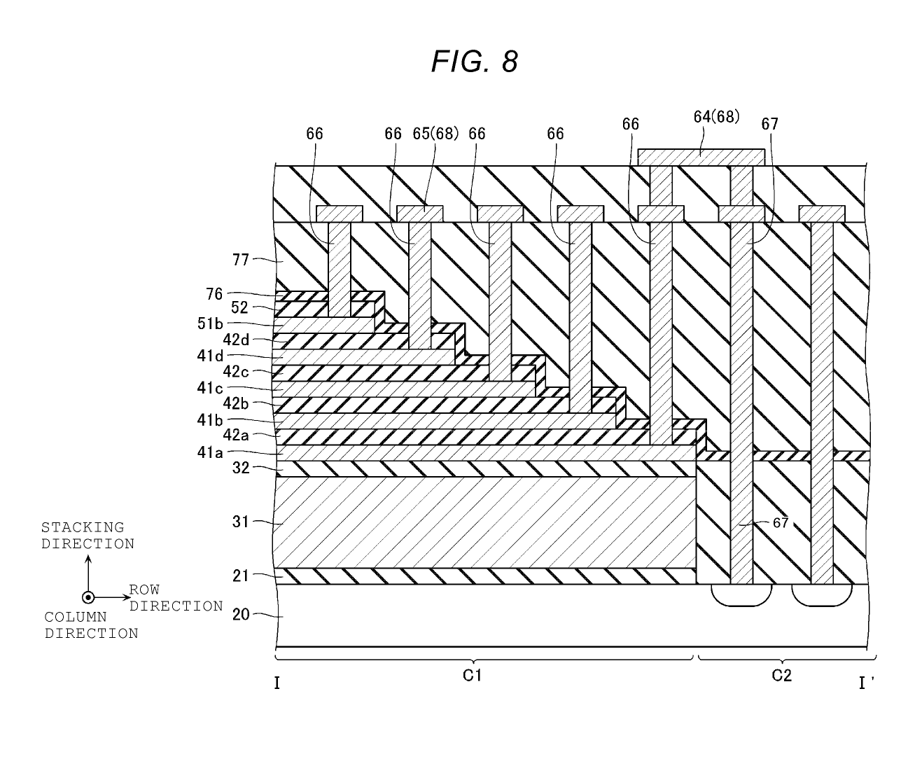

FIG. 8 is a cross-sectional view of the first contact region C1 taken along a line I-I′ in FIG. 6 as viewed in the direction indicated by an arrow. In the first contact region C1, end portions of the word line conductive layers 41a to 41d and the drain-side conductive layers 51b on a row direction side are formed in a projecting manner toward a second contact region C2 side such that the lower the layer is positioned, the more the end portion projects toward a second contact region C2 side. The whole end portions of the word line conductive layers 41a to 41d and the drain-side conductive layers 51b on a row direction side are formed in a stepwise manner. The interlayer insulation layers 42a to 42d cover upper surfaces of the word line conductive layers 41a to 41d. Upper surfaces and side surfaces of the word line conductive layers 41a to 41d and the interlayer insulation layers 42a to 42d are covered with a protective layer 76. An upper surface of the protective layer 76 is covered with an insulation layer 77. The first contacts 66 which penetrate the insulation layer 77, the protective layer 76 and the interlayer insulation layers 42a to 42d are respectively connected to the word line conductive layers 41a to 41d. In FIG. 8, all positions of the first contacts 66 in the column direction are the same as each other. However, the first contacts 66 are illustrated at the same position simply for the sake of convenience of the explanation, and the positions of the first contacts 66 may be displaced from each other in the column direction. Further, for example, an end portion of the back gate conductive layer 31 in the row direction may project from an end portion of the word line conductive layer 41a in the row direction such that a contact wire with the back gate conductive layer 31 may be formed in the stacking direction. The first contacts 66 are connected with the wires 64, 65 arranged above the first contacts 66. The wires 64, 65 are connected with a circuit such as a row decoder or the like formed on the semiconductor substrate 20 via the second contacts 67 in the second contact region C2. The wires 64 and the wires 65 are arranged on different layers. In this example, the wires 65 are arranged on the layer above the layer on which the wires 64 are formed. A pitch at which the wires 65 are arranged may be set smaller than a pitch at which the wires 64 are arranged.

In this embodiment, even when the width of the memory block MB in the column direction is narrowed, the word lines WL and the selection gate lines SGS, SGD can be desirably pulled out so that the number of memory units MU included in the memory block MB can be decreased. Accordingly, in the semiconductor storage device according to this embodiment, a block size which is a unit for erasing data can be decreased and hence, it is possible to provide a semiconductor storage device which can perform a desired control.

As a comparison example, it may be possible to decrease the width of the memory block MB by ensuring a space where the second contacts 67 are arranged by partially narrowing widths of the word line conductive layers 41a to 41d and the drain-side conductive layers 51 or by forming opening portions in the word line conductive layers 41a to 41d and the drain-side conductive layers 51 and, at the same time, by arranging the first contacts 66 and the wires 68 on both sides of the arrangement space for the second contacts 67 in the row direction in a distributed manner. In this case, however, the widths of the word line conductive layers 41a to 41d and the drain-side conductive layers 51 are partially narrowed and hence, the wire resistance is increased. In this respect, according to this embodiment, the wire resistance can be decreased without partially narrowing the widths of the word line conductive layers 41a to 41d and the drain-side conductive layer 51.

### Method of Manufacturing Semiconductor Storage Device According to First Embodiment

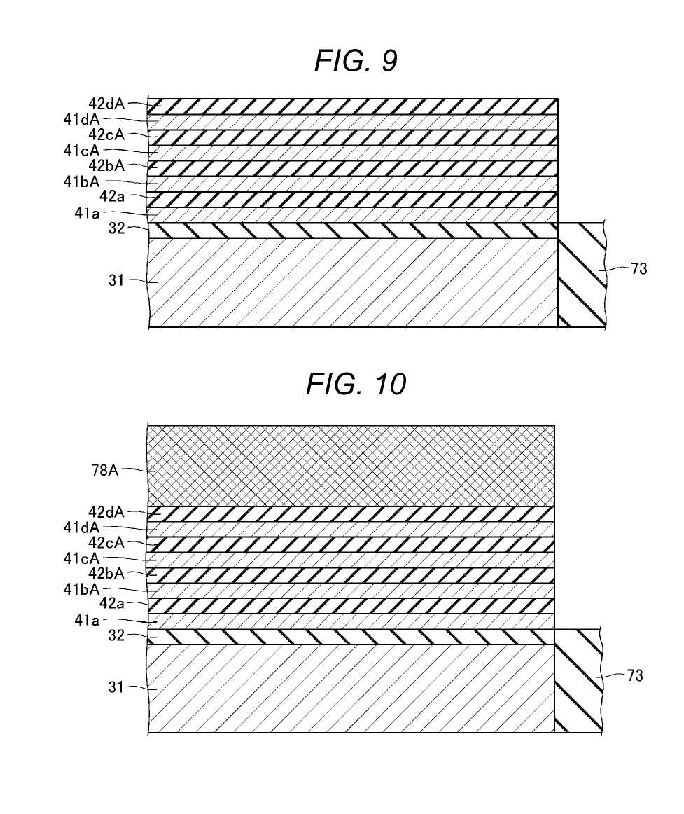

Next, a method of manufacturing the semiconductor storage device according to the first embodiment is explained. In manufacturing the semiconductor storage device according to this embodiment, firstly, as shown in FIG. 9, the back gate conductive layer 31, the back gate insulation layer 32, the insulation layer 73, the word line conductive layer 41a, word line conductive layer forming layers 41bA to 41dA, the interlayer insulation layer 42a and interlayer insulation layer forming layers 42bA to 42dA are sequentially formed.

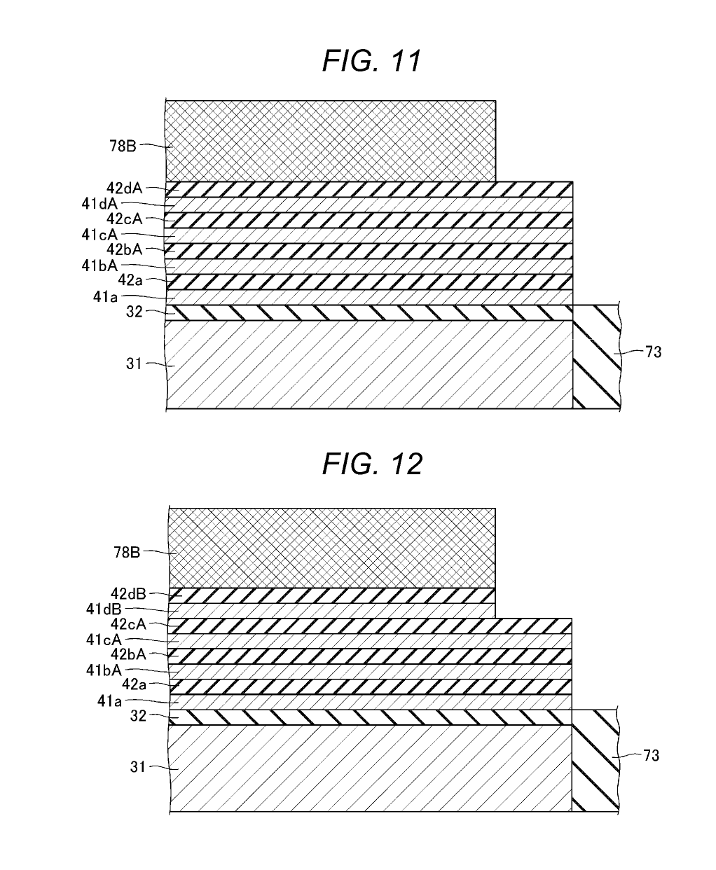

Next, as shown in FIG. 10, a resist layer 78A is formed on the interlayer insulation layer forming layer 42dA. Then, as shown in FIG. 11, a resist layer 78B is formed by removing a part of the resist layer 78A by slimming the resist layer 78A whereby a part of an upper surface of the interlayer insulation layer forming layer 42dA is exposed. Next, as shown in FIG. 12, a part of the interlayer insulation layer forming layer 42dA and a part of the word line conductive layer forming layer 41dA are removed by etching using the resist layer 78B as a mask thus forming an interlayer insulation layer forming layer 42dB and a word line conductive layer forming layer 41dB. Further, a part of an upper surface of the interlayer insulation layer forming layer 42cA is exposed.

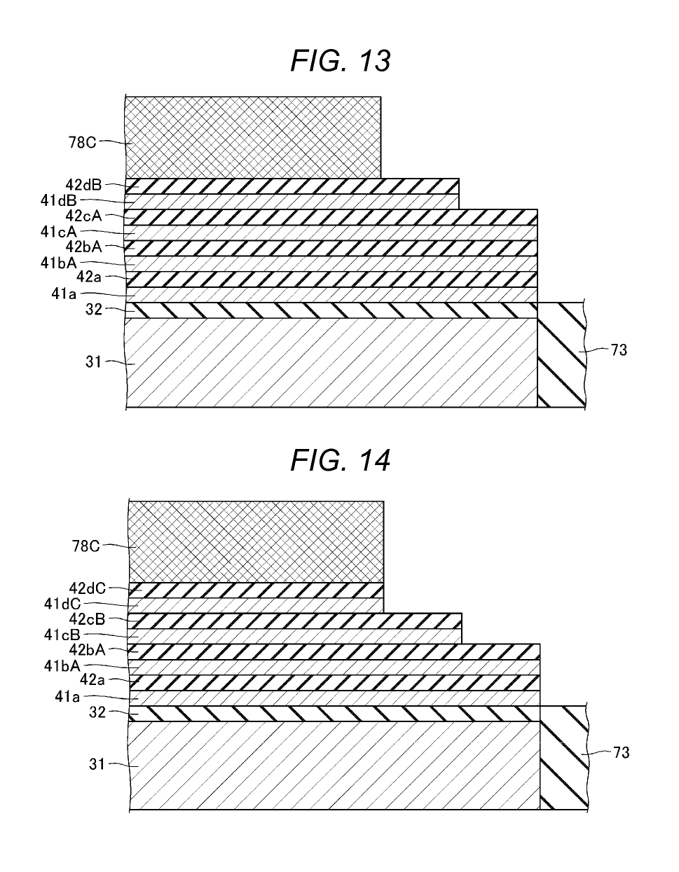

Then, as shown in FIG. 13, a resist layer 78C is formed by removing a part of the resist layer 78B by slimming the resist layer 78B whereby a part of an upper surface of the interlayer insulation layer forming layer 42dB is further exposed. Next, as shown in FIG. 14, parts of the interlayer insulation layer forming layers 42dB, 42cA and parts of the word line conductive layer forming layers 41dB, 41cA are removed by etching using the resist layer 78C as a mask thus forming interlayer insulation layer forming layers 42dC, 42cB and word line conductive layer forming layers 41dC, 41cB. Further, a part of an upper surface of the interlayer insulation layer forming layer 42bA is exposed.

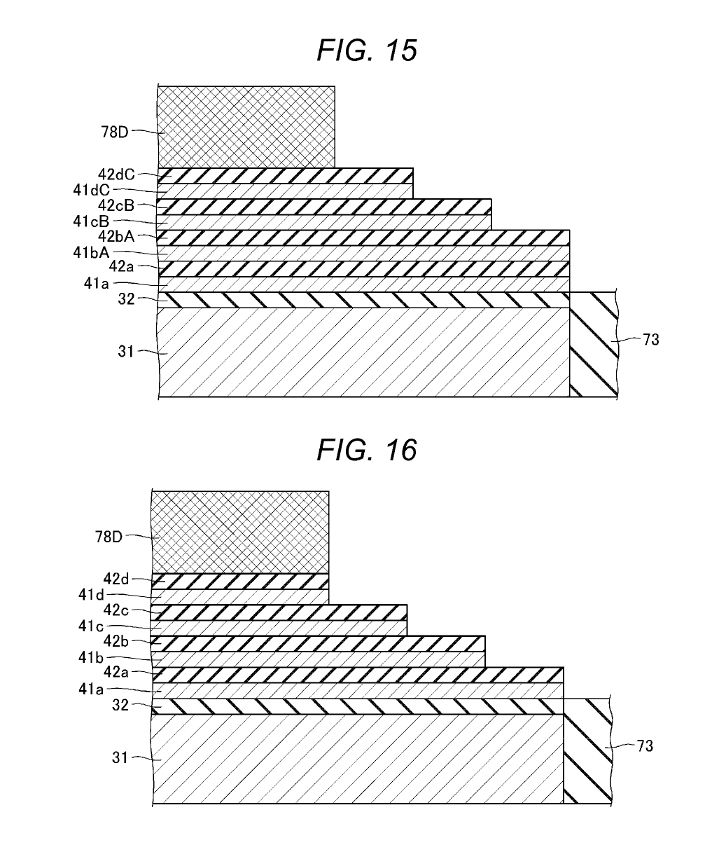

Then, as shown in FIG. 15, a resist layer 78D is formed by removing a part of the resist layer 78C by slimming the resist layer 78C whereby a part of an upper surface of the interlayer insulation layer forming layer 42dC is further exposed. Next, as shown in FIG. 16, parts of the interlayer insulation layer forming layers 42dC, 42cB, 42bA and parts of the word line conductive layer forming layers 41dC, 41cB, 41bA are removed by etching using the resist layer 78D as a mask thus forming the interlayer insulation layers 42d, 42c, 42b, and the word line conductive layers 41d, 41c, 41b.

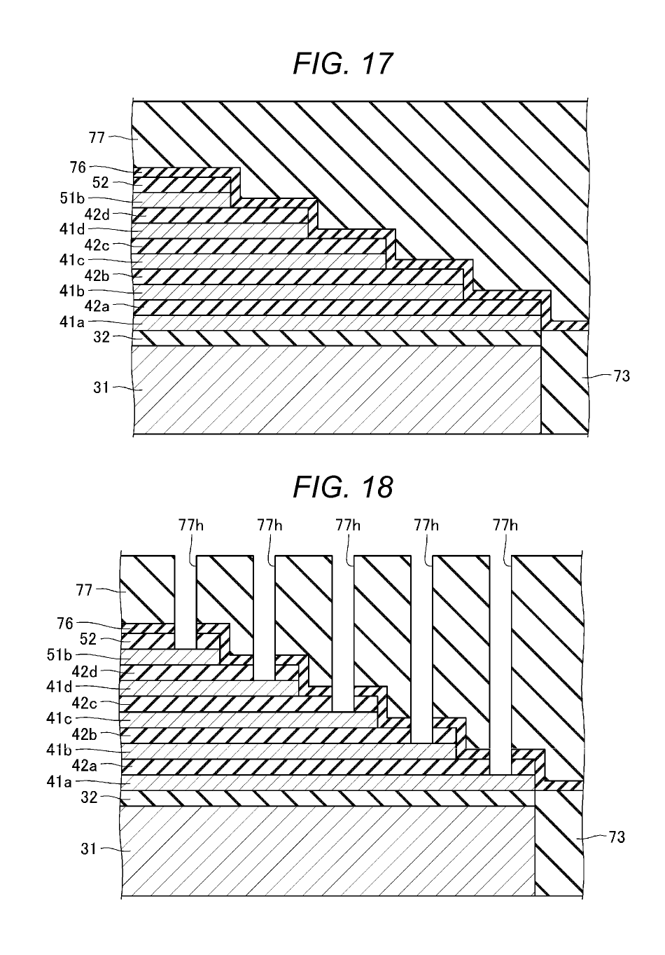

Then, as shown in FIG. 17, the resist layer 78D is removed thus forming the source-line-side conductive layer 51a and the drain-side conductive layer 51b and the selection gate insulation layer 52 on an upper surface of the interlayer insulation layer 42d. Upper surfaces and side surfaces of the interlayer insulation layers 42a to 42d, the word line conductive layers 41a to 41d, the source-line-side conductive layer 51a, the drain-side conductive layer 51b and the selection gate insulation layer 52 which are formed in a stepwise manner and are exposed are covered with the protective layer 76. The protective layer 76 is further covered with the insulation layer 77.

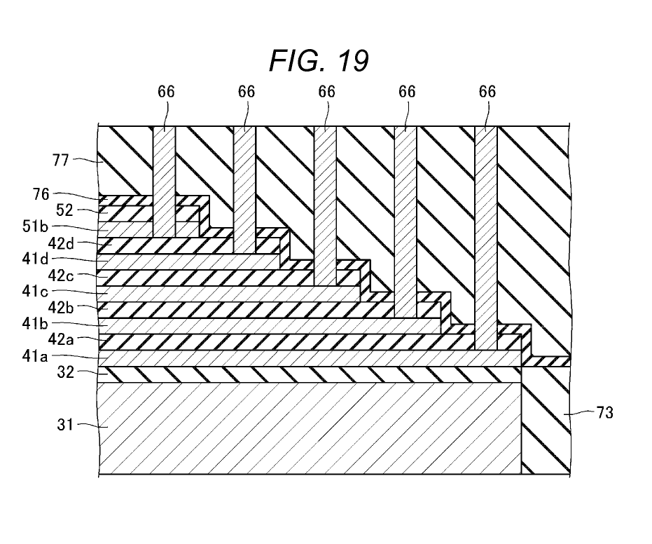

Next, as shown in FIG. 18, a plurality of contact holes 77h are formed in the insulation layer 77, the protective layer 76, the interlayer insulation layers 42a to 42d and the selection gate insulation layer 52. Through the plurality of these contact holes 77h, upper surfaces of the word line conductive layers 41a to 41d, the source-line-side conductive layers 51a and the drain-side conductive layers 51b are exposed. When an etching rate of the insulation layer 77 is sufficiently greater than an etching rate of the protective layer 76, the contact holes 77h can be collectively formed. Then, as shown in FIG. 19, the contacts 66 are formed in the contact holes 77h. As a method for forming the contacts 66, various methods can be adopted.

Thereafter, the source lines 61 and wires 65 arranged above the source lines 61 (FIG. 7 and FIG. 8) are formed on the same wiring layer, and the bit lines 62 and the liens 64 arranged above the bit lines 62 (FIG. 7 and FIG. 8) are formed on the same wiring layer. Accordingly, in the method of manufacturing the semiconductor storage device according to this embodiment, the configuration of the semiconductor storage device can be realized using the substantially same number of steps as conventional methods of manufacturing a semiconductor storage device.

### Semiconductor Storage Device According to Second Embodiment

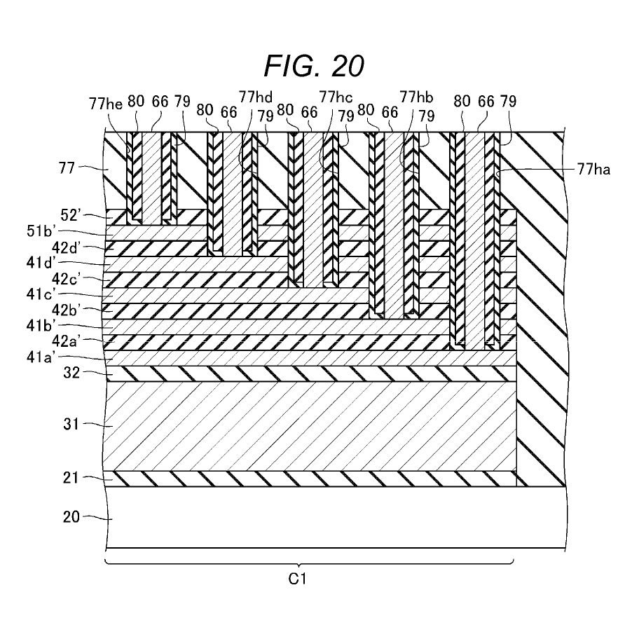

Next, a semiconductor storage device according to the second embodiment is explained. FIG. 20 is a cross-sectional view of a first contact region C1 of the semiconductor storage device according to the second embodiment. The semiconductor storage device according to this embodiment basically has the substantially same configuration as the semiconductor storage device according to the first embodiment. However, as shown in FIG. 20, the semiconductor storage device according to the second embodiment differs from the semiconductor storage device according to the first embodiment with respect to the configuration of end portions in the row direction of word line conductive layers 41a′ to 41d′ and a drain-side conductive layer 51b′ (also a source-side conductive layer 51a′) in the first contact region C1. That is, in this embodiment, positions of the end portions in the row direction of the word line conductive layers 41a′ to 41d′ and the drain-side conductive layer 51b′ (also the source-side conductive layer 51a′) in the first contact region C1 are aligned with each other. First contacts 66 are formed in a penetrating manner in the conductive layers above the conductive layer to which the first contacts 66 are connected. Outer peripheries of the first contacts 66 are covered with insulation layers 79, 80 thus preventing the conduction between the first contacts 66 and the conductive layer arranged above the first contacts 66.

Next, a method of manufacturing the semiconductor storage device according to this embodiment is explained. In forming the semiconductor storage device according to this embodiment, the number of masks corresponds to the different depths of the contact holes, and the number of times etching is performed corresponds to the number of masks. However, in this embodiment, the formation of the deep contact holes is performed along with the formation of the shallow contact holes by combining a plurality of masks and so decreasing the number of masks used and the process time.

For example, assuming that the number of different depths of the contact holes is n and these depths are expressed as 1×d to n×d respectively, k(1≦k≦n) can be expressed by a binary number. Accordingly, assuming that n contact holes are manufactured by a plurality of masks, the number of which corresponds to the number of digits x when n is expressed by a binary number, the number of masks used can be decreased from n pieces to x pieces, and the number of times of etching can be decreased from n times to x times.

For example, as shown in FIG. 20, in this embodiment, the number of different depths of the contact holes is five (n=5), and 5 is expressed by 101 by a binary number, and so x is 3. Accordingly, the number of masks used can be decreased from 5 pieces to 3 pieces, and the number of times of etching can be decreased from 5 times to 3 times.

As shown in FIG. 20, the depth of the contact hole 77ha corresponding to the word line conductive layer 41a′ amounts to 5 (101 in a binary number) layers, the depth of the contact hole 77hb corresponding to the word line conductive layer 41b′ amounts to 4 (100 in a binary number) layers, the depth of the contact hole 77hc corresponding to the word line conductive layer 41c′ amounts to 3 (011 in a binary number) layers, the depth of the contact hole 77hd corresponding to the word line conductive layer 41d′ amounts to 2 (010 in a binary number) layers, and the depth of the contact hole 77he corresponding to the source-line-side conductive layer 51a′ and the drain-side conductive layers 51b′ amounts to 1 (001 in a binary number) layer. Accordingly, in performing etching corresponding to 1 layer, a contact hole is formed in portions corresponding to the contact holes 77ha, 77hc and 77he where the first digit of the binary number is 1. In performing etching corresponding to 2 layers, a contact hole is formed in portions corresponding to the contact holes 77hc and 77hd where the second digit of the binary number is 1. In performing etching corresponding to 4 layers, a contact hole is formed in portions corresponding to the contact holes 77ha and 77hb where the third digit of the binary number is 1.

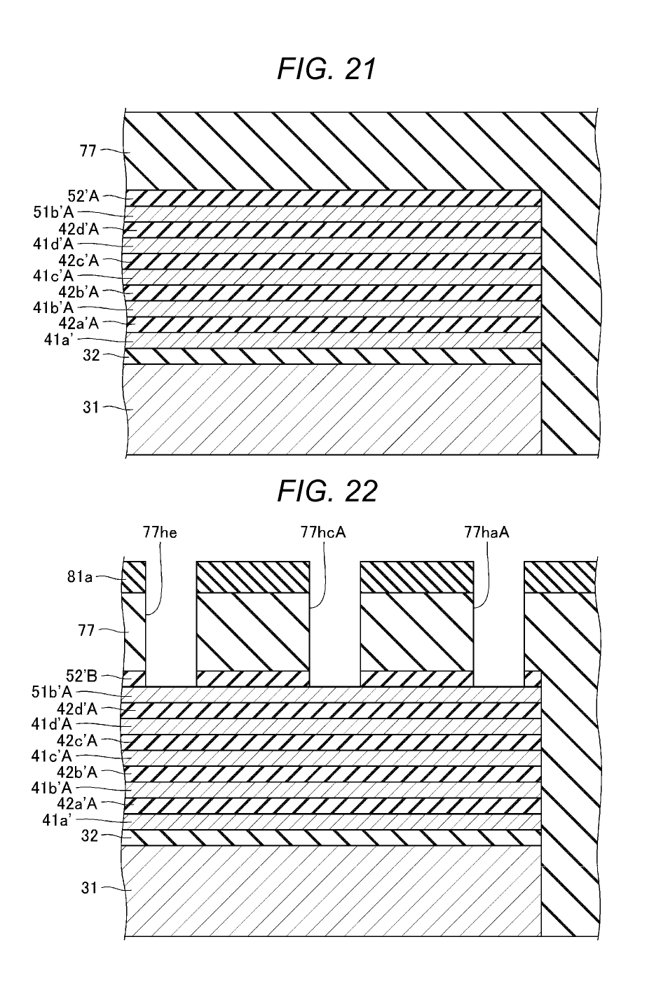

In the method of manufacturing the semiconductor storage device according to this embodiment, firstly, as shown in FIG. 21, a back gate conductive layer 31, a back gate insulation layer 32, a word line conductive layer 41a′, word line conductive layer forming layers 41b′A to 41d′A, interlayer insulation layer forming layers 42a′A to 42d′A, a source-line-side conductive layer forming layer 51a′A, a drain-side conductive layer forming layer 51b′A, and a selection gate insulation layer forming layer 52′A are formed. Then, an upper surface and side surfaces of the stacked body are covered with an insulation layer 77.

Next, as shown in FIG. 22, a resist 81a is formed using a first mask, and the selection gate insulation layer forming layer 52′B is formed by removing a part of the selection gate insulation layer forming layer 52′A. In this step, the contact holes 77he and contact forming holes 77hcA and 77ha are formed through which upper surfaces of the source-line-side conductive layer forming layer 51a′A and the drain-side conductive layer forming layer 51b′A are exposed.

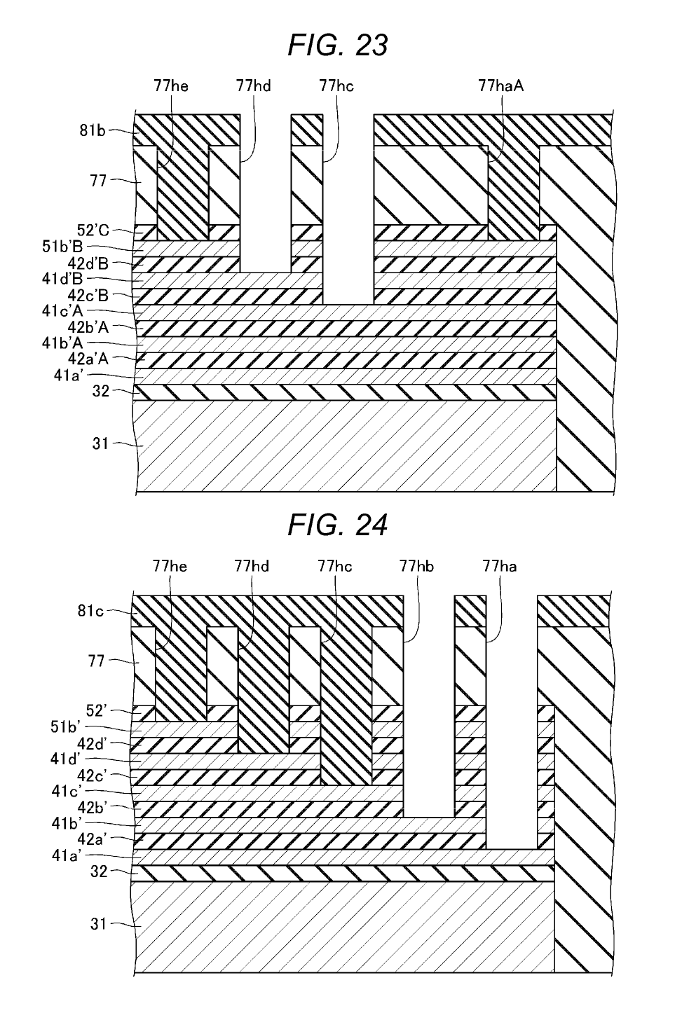

Next, as shown in FIG. 23, a resist 81b is formed using a second mask, and the word line conductive layer forming layer 41d′B, the interlayer insulation layer forming layers 42c′B, 42d′B, the source-line-side conductive layer forming layer 51a′B, the drain-side conductive layer forming layer 51b′B and the selection gate insulation layer forming layer 52′C are formed by removing a part of the word line conductive layer forming layer 41d′A, a part of the interlayer insulation layer forming layers 42c′A, 42d′A, a part of the source-line-side conductive layer forming layer 51a′A, a part of the drain-side conductive layer forming layer 51b′A and a part of the selection gate insulation layer forming layer 52′B. In this step, the contact hole 77hd through which an upper surface of the word line conductive layer 41d′ is exposed and the contact hole 77hc through which an upper surface of the word line conductive layer 41c′ is exposed are formed.

Next, as shown in FIG. 24, a resist 81c is formed using a third mask, and the word line conductive layers 41b′ to 41d′, the interlayer insulation layer forming layers 42a′ to 42d′, the source-line-side conductive layer forming layer 51a′, the drain-side conductive layer forming layer 51b′ and the selection gate insulation layer forming layer 52′ are formed by removing parts of the word line conductive layer forming layers 41b′A, 41c′A, 41d′B, parts of the interlayer insulation layer forming layers 42a′A, 42b′A, 42c′B, 42d′B, a part of the source-line-side conductive layer forming layer 51a′B, a part of the drain-side conductive layer forming layer 51b′B and a part of the selection gate insulation layer forming layer 52′C. In this step, the contact hole 77hb through which an upper surface of the word line conductive layer 41b′ is exposed and the contact hole 77ha where an upper surface of the word line conductive layer 41a′ is exposed are formed.

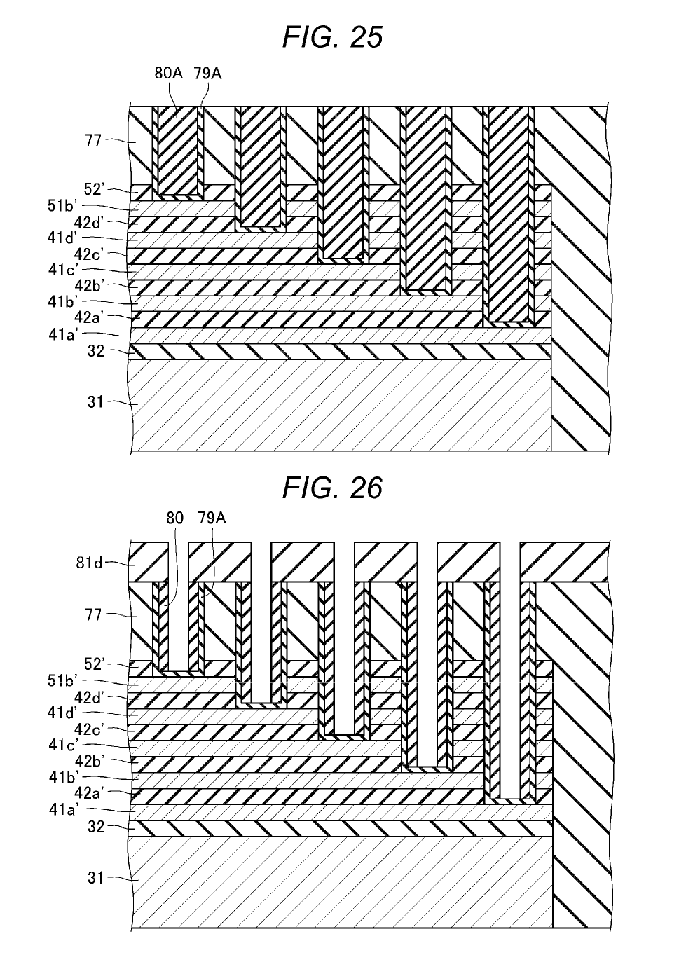

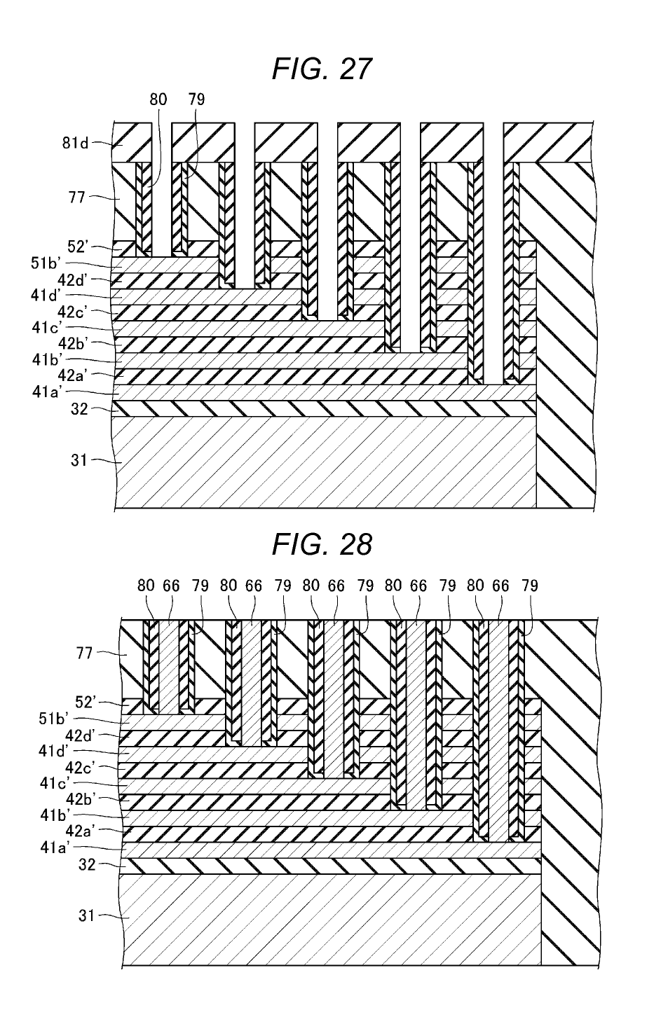

Then, as shown in FIG. 25, an insulation layer 79A is formed such that the insulation layer 79A covers side walls and bottom surfaces of the contact holes 77h (77ha to 77he) and, subsequently, an insulation layer 80A is embedded in the contact holes 77h (77ha to 77he). An etching rate of the insulation layer 80A is higher than an etching rate of the insulation layer 79A. Then, as shown in FIG. 26, a mask 81d is formed so as to cover upper surfaces of the insulation layers 77, 79A and 80A, and contact holes are formed by etching. The etching rate of the insulation layer 80A is higher than the etching rate of the insulation layer 79A and hence, firstly, a bottom surface of the insulation layer 79A is exposed by removing a part of the insulation layer 80A with respect to all contact holes and, thereafter, as shown in FIG. 27, the exposed parts of the insulation layer 79A are removed thus exposing the word line conductive layers 41a′ to 41d′. Contacts 66 are formed as shown in FIG. 28 after the word line conductive layers 41a′ to 41d′ are exposed.

A method of etching, a design of mask and the like can be suitably changed. For example, assuming that the depths of all contact holes can be expressed as a sum of a plurality of depths (d₁, d₂, . . . , dₓ), masks, the number x of which corresponds to the plurality of depths, are prepared. When the depth of the predetermined contact hole is expressed by the above-mentioned sum of depths and the sum includes a depth dₐ corresponding to an a(=1 to x)-th mask as a term, a hole is formed in a portion of the mask corresponding to the predetermined contact hole, and etching of the depth dₐ corresponding to the a-th mask is performed using the a-th mask. In this case, the number of masks used and the number of times of etching can be decreased. Further, a process time may be theoretically minimized by minimizing the sum of d₁ to dₓ. In this case, the sum of d₁ to dₓ may be set such that the sum of d₁ to dₓ agrees with the depth of the deepest contact hole. Further, when the method of expressing the depth is not univocally determined, by setting the depth such that the number of kinds of terms is minimized, the influence caused by an error which is generated at the time of positioning the mask may be decreased.

### Semiconductor Storage Device According to Third Embodiment

Next, a semiconductor storage device according to the third embodiment is explained. The semiconductor storage device according to this embodiment basically has the substantially same configuration as the semiconductor storage device according to the first embodiment. However, a memory block MB-3 according to this embodiment includes word line conductive layers 41a to 41i stacked in nine layers. The memory block MB-3 according to this embodiment also differs from the semiconductor storage devices according to the first and second embodiments with respect to the configuration of a first contact region C1.

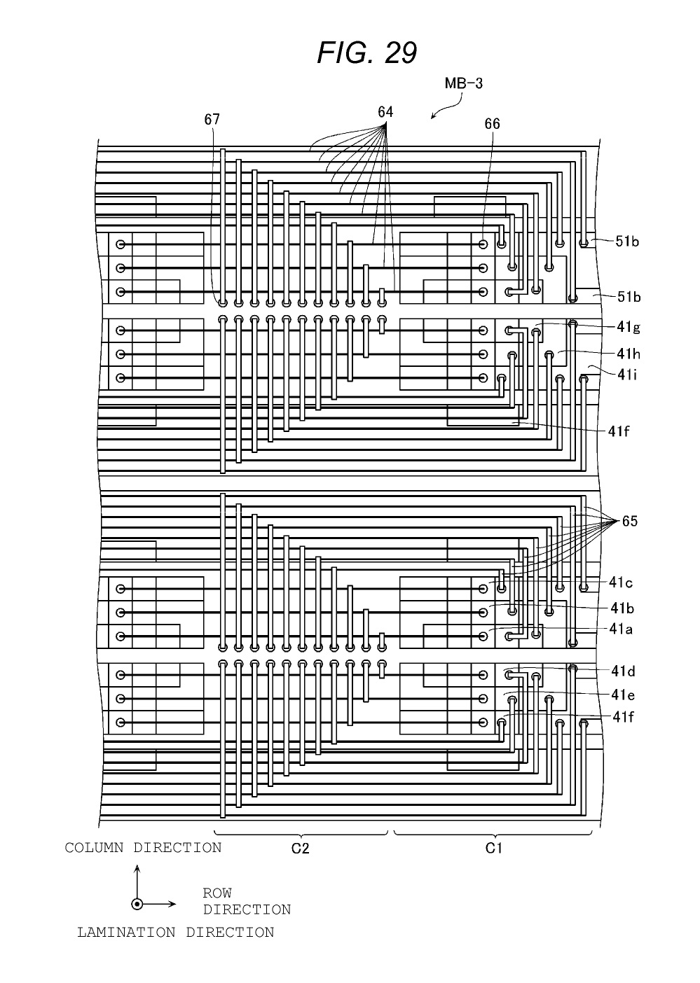

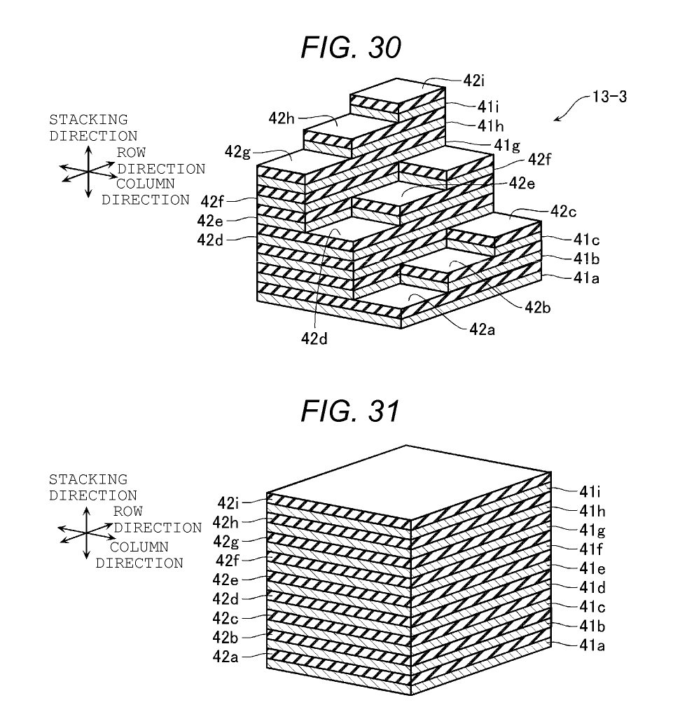

FIG. 29 is a schematic plan view for illustrating the configuration of the semiconductor storage device according to this embodiment, and FIG. 30 is a perspective view of the semiconductor storage device according to this embodiment. End portions in the row direction of the word line conductive layers 41a to 41i in the first contact region C1 according to this embodiment are formed such that the end portions of the conductive layers at the lower positions project more toward a second contact region C2 side in the row direction. First contacts 66 are pulled out from the end portions in the row direction of the word line conductive layers 41a to 41i. When such a shape is adopted, the number of steps necessary for etching can be decreased and hence, a manufacturing cost can be decreased. Further, end portions where heights in the stacking direction differ are formed not only in the row direction but also in the column direction in such a contact method and hence, areas of wire draw-out portions can be decreased.

As shown in FIG. 29, when the first contact region C1 is formed by the method of this embodiment, there maybe a case where when such a part is processed, the processing influences a memory block MB-3 arranged adjacent to the part in the column direction so that widths of the word line conductive layers 41g to 41i are narrowed whereby the word line conductive layer 41f is exposed. It is considered such influences can be eliminated using a hard mask or other means.

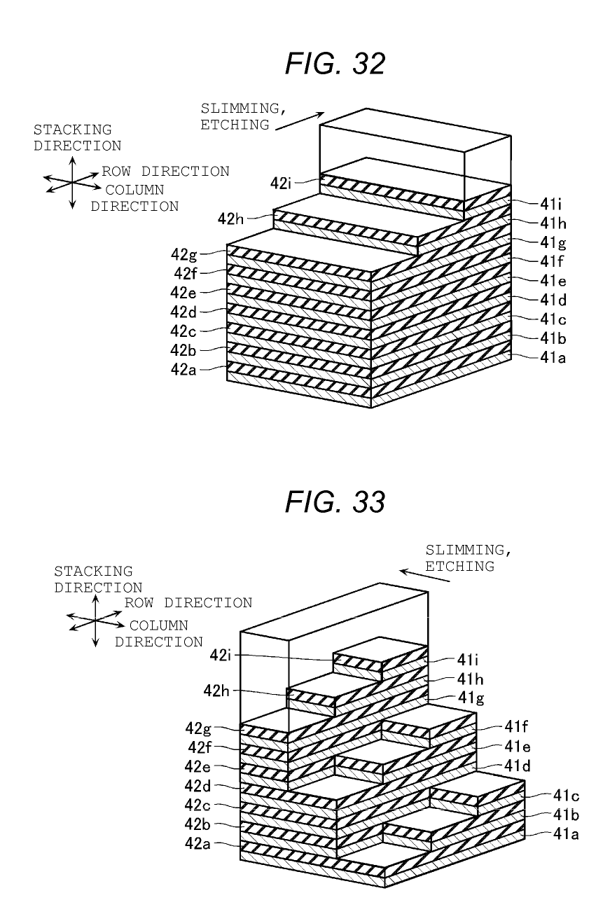

Next, a method of manufacturing the semiconductor storage device according to this embodiment is explained. The method of manufacturing the semiconductor storage device according to this embodiment is substantially the same as the method of manufacturing the semiconductor storage device according to the first embodiment, and differs with respect to a step of forming the first contact region C1. As shown in FIG. 31, word line conductive layers 41a to 41i are alternately stacked with interlayer insulation layers 42a to 42i sandwiched therebetween. Then, as shown in FIG. 32, masks are stacked on the stacked body, and slimming of the word line conductive layers 41g to 41i and the interlayer insulation layers 42g to 42i in the row direction of the masks is performed by etching the word line conductive layers 41g to 41i and the interlayer insulation layers 42g to 42i one layer by one layer. Next, as shown in FIG. 33, the masks are removed once and, thereafter, masks are again stacked on the stacked body, and slimming of the word line conductive layers 41a to 41i and the interlayer insulation layers 42a to 42i in the column direction of the masks is performed by etching the word line conductive layers 41a to 41i and the interlayer insulation layers 42a to 42i such that three layers are etched each time. Then, steps which are substantially equal to the corresponding steps of the method of manufacturing the semiconductor storage device according to the first embodiment are performed. Due to such a method of manufacturing the semiconductor storage device, the configuration shown in FIG. 29 and FIG. 30 can be formed.

### Semiconductor Storage Devices According to Other Embodiments

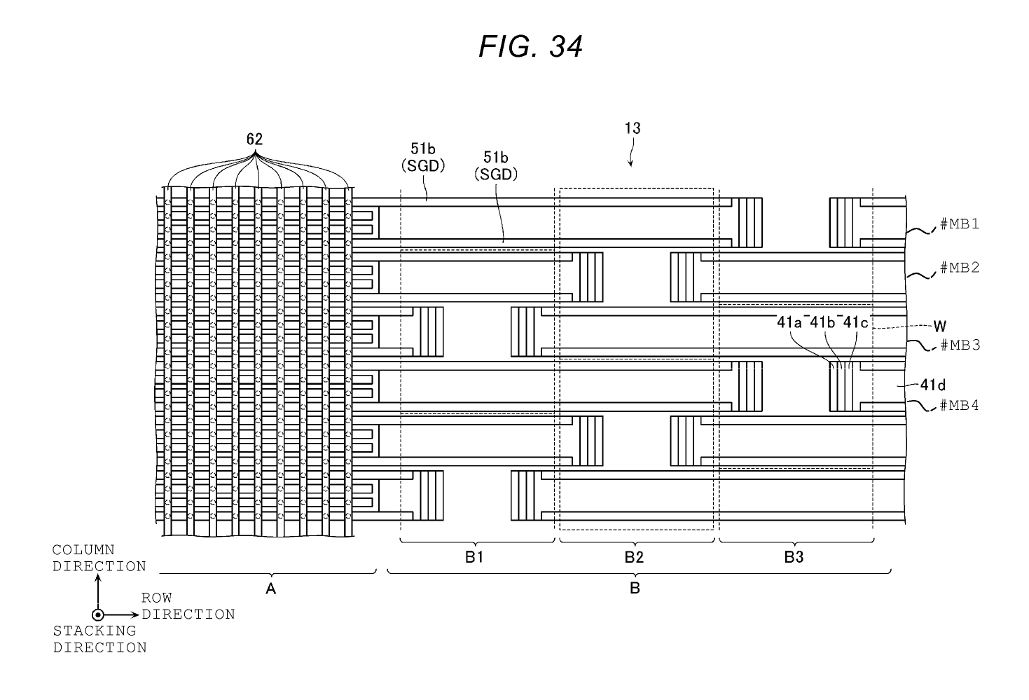

In the first embodiment described above, the wires 64 and 65 which are connected to the predetermined memory block MB are positioned above the memory block MB arranged adjacent to one side of the predetermined memory block MB in the column direction in FIG. 7. On the other hand, in the portion of the memory cell array shown in FIG. 34, wires corresponding to the wires 64 and 65 of FIG. 7 (hereinafter referred to as “connecting wires”) may be positioned above the memory blocks MB arranged adjacent to both sides of the predetermined memory block MB in the column direction. By adopting such a wiring pattern, the connecting wires can be drawn out from four sides.

Furthermore, a layout of the wires 64 and 65 may be modified as follows. Referring to FIG. 34, the connecting wires of the memory block MB#1 would be disposed above the memory blocks MB#2 and MB#3 in the area B3. The connecting wires of the memory block MB#2 would be disposed above the memory blocks MB#1 and MB#3 in the area B2. The connecting wires of the memory block MB#3 would be disposed above the memory blocks MB#1 and MB#2 in the area B1. That is, all of the connecting wires of the predetermined memory blocks MB in the column direction (e.g., MB#1, MB#2, MB#3 in the example given above) would be disposed within an area which is above the predetermined memory blocks MB.

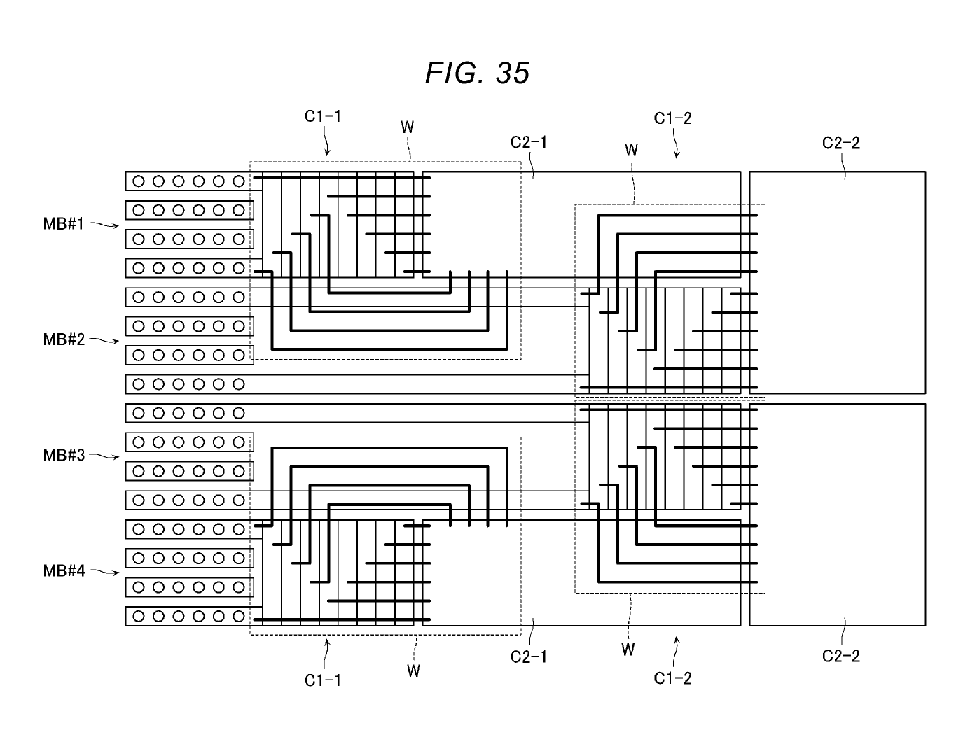

Further, as shown in FIG. 35, it may be possible to set a width in the column direction of a second contact region C2-1 of the predetermined memory block MB substantially equal to a width of the predetermined memory block MB and to set a width in the column direction of a second contact region C2-2 of another memory block MB arranged adjacent to the predetermined memory block MB substantially equal to a width in the column direction which the predetermined memory block MB and the another memory block MB occupy.

While certain embodiments have been described, these embodiments have been presented by way of the example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, although the above-mentioned embodiments relate to the pipe-type semiconductor storage device, it is needless to say that the exemplified embodiments are also applicable to an I-type semiconductor storage device which uses a pillar semiconductor as a channel body of a memory unit MU.

What is claimed is:

1. A semiconductor storage device comprising:
a semiconductor substrate;
a plurality of first word lines that are stacked above the substrate and extend in a row direction;
a plurality of second word lines that are stacked above the substrate, extend in the row direction, are electrically connected to the first word lines, and are separated from the first word lines by a first region;
a plurality of third word lines that are stacked above the substrate and extend in the row direction; and
a plurality of fourth word lines that are stacked above the substrate, extend in the row direction, are electrically connected to the third word lines, and are separated from the third word lines by a second region,
wherein a position of the first region is offset with respect to a position of the second region in the row direction.

2. The semiconductor storage device of claim 1, wherein the first word lines are electrically connected to the second word lines such that each pair of the first and second word lines that are at a same height above the substrate is electrically connected to each other, and the third word lines are electrically connected to the fourth word lines such that each pair of the third and fourth word lines that are at a same height above the substrate is electrically connected to each other.

3. The semiconductor storage device of claim 2, wherein a plurality of wires that electrically connect the first word lines to the second word lines include a first wire that spans the first region and a second wire that extends over the third word lines, and a plurality of wires that electrically connect the third word lines to the fourth word lines include a third wire that spans the second region and a fourth wire that extends over the second word lines.

4. The semiconductor storage device of claim 1, wherein end portions of the first and second word lines that are closer to the substrate extend closer to the first region and end portions of the third and fourth word lines that are closer to the substrate extend closer to the second region.

5. The semiconductor storage device of claim 1, further comprising:
a plurality of fifth word lines that are stacked above the substrate, and extend in the row direction; and
a plurality of sixth word lines that are stacked above the substrate, extend in the row direction, are electrically connected to the fifth word lines, and are separated from the fifth word lines by a third region,
wherein a position of the third region is adjacent and continuous with respect to the first region.

6. The semiconductor storage device of claim 1, further comprising:
a plurality of fifth word lines that are stacked above the substrate and extend in the row direction; and
a plurality of sixth word lines that are stacked above the substrate, extend in the row direction, are electrically connected to the fifth word lines, and are separated from the fifth word lines by a third region,
wherein a position of the third region is offset with respect to the positions of the first and second regions in the row direction.

7. The semiconductor storage device of claim 6, wherein the first and second word lines are adjacent to the third and fourth word lines in a column direction, and the third and fourth word lines are adjacent to the fifth and sixth word lines in the column direction.

8. The semiconductor storage device of claim 7, further comprising:
a plurality of seventh word lines that are stacked above the substrate and extend in the row direction; and
a plurality of eighth word lines that are stacked above the substrate, extend in the row direction, are electrically connected to the seventh word lines, and are separated from the seventh word lines by a fourth region,
wherein a position of the fourth region is aligned with respect to the position of the first region in the row direction, and the fifth and sixth word lines are adjacent to the seventh and eighth word lines in the column direction.

9. A semiconductor storage device comprising:
a semiconductor substrate;
a plurality of first word lines that are stacked above the substrate and extend in a row direction;
a plurality of second word lines that are stacked above the substrate, extend in the row direction, are electrically connected to the first word lines, and are separated from the first word lines by a first region;
a plurality of third word lines that are stacked above the substrate and extend in the row direction; and
a plurality of fourth word lines that are stacked above the substrate, extend in the row direction, are electrically connected to the third word lines, and are separated from the third word lines by a second region,
wherein a position of the first region is offset with respect to a position of the second region in the row direction, and widths of the first, second, and third word lines in a column direction are equal and less than a width of the fourth word line in the column direction.

10. The semiconductor storage device of claim 9, wherein the first word lines are electrically connected to the second word lines such that each pair of the first and second word lines that are at a same height above the substrate is electrically connected to each other, and the third word lines are electrically connected to the fourth word lines such that each pair of the third and fourth word lines that are at a same height above the substrate is electrically connected to each other.

11. The semiconductor storage device of claim 10, wherein a plurality of wires that electrically connect the first word lines to the second word lines include first wires that span the first region and second wires that extend over the third word lines, and a plurality of wires that electrically connect the third word lines to the fourth word lines include third wires that span the second region and fourth wires that extend over the second word lines.

12. The semiconductor storage device of claim 11, wherein the fourth wires that extend over the second word lines are connected to the fourth word lines at points on the fourth word lines that are aligned with the first and second word lines in the row direction.

13. The semiconductor storage device of claim 12, wherein end portions of the first word lines that are closer to the substrate extend closer to the first region and end portions of the third word lines that are closer to the substrate extend closer to the second region.

14. The semiconductor storage device of claim 13, wherein end portions of all of the second word lines are equidistant to the first region and end portions of all of the fourth word lines are equidistant to the second region.

15. The semiconductor storage device of claim 9, wherein the first and second word lines are adjacent to the third word lines in the column direction, and the fourth word lines are not adjacent to either the first word lines or the second word lines in the column direction.

16. A semiconductor storage device comprising:
a semiconductor substrate;
a plurality of first word lines that are stacked above the substrate and extend in a row direction; and
a plurality of second word lines that are stacked above the substrate, extend in the row direction, are electrically connected to the first word lines, and are separated from the first word lines,
wherein the first word lines include a lower stack of first word lines and an upper stack of first word lines, and end portions of the first word lines that are in the lower stack and closer to the substrate extend closer to the second word lines and end portions of the first word lines that are in the upper stack and closer to the substrate extend closer to the second word lines.

17. The semiconductor storage device of claim 16, wherein the first word lines include a middle stack of first word lines and end portions of the first word lines that are in the middle stack and closer to the substrate extend closer to the second word lines.

18. The semiconductor storage device of claim 17, wherein widths of the first word lines in the lower stack in a column direction are larger than those of the first word lines in the middle stack, and the widths of the first word lines in the middle stack in the column direction are larger than those of the first word lines in the upper stack.

19. The semiconductor storage device of claim 18, wherein contact surfaces of the first word lines in the middle stack are between contact surfaces of the first word lines in the lower stack and contact surfaces of the first word lines in the upper stack in the column direction.

20. The semiconductor storage device of claim 17, wherein the end portion of the lowermost first word line in the lower stack is aligned in the row direction with the end portion of the lowermost first word line in the middle stack and with the end portion of the lowermost first word line in the upper stack.
